(19) United States
(12) Patent Application Publication
(10) Pub. No.: US 2010/0041212 A1
(43) Pub. Date: Feb. 18, 2010

(54) FILM FORMING METHOD AND FILM FORMING APPARATUS

(75) Inventors: Akira Jinzu, Susono-shi (JP); Seiichi Takahashi, Susono-shi (JP); Eiichi Mizuo, Susono-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, INC., Chigasaki-shi (JP)

(21) Appl. No.: 12/444,246

(22) PCT Filed: Oct. 3, 2007
(86) PCT No.: PCT/JP2007/069389

§ 371 Date: Oct. 20, 2009

(30) Foreign Application Priority Data
Oct. 4, 2006 (JP) P2006-272962

(51) Int. Cl. H01L 21/20

(52) U.S. Cl. 438/478; 118/725; 257/E21.09

(57) ABSTRACT

The present invention provides a film forming apparatus capable of removing a natural oxide film of a silicon substrate W at a very low temperature, as compared to the related art. The natural oxide film is removed at a low temperature by converting the natural oxide film on the silicon substrate W into a volatile material and evaporating the volatile material. The natural oxide film can be converted into volatile ammonium fluorosilicate by reaction with ammonium fluoride. A single crystal SiGe film can be grown on the silicon substrate W from which the natural oxide film is removed. The film forming apparatus includes an etching chamber, a SiGe growing chamber, and a substrate transport chamber that transports the silicon substrate in a controlled atmosphere.

### TECHNICAL FIELD

The present invention relates to a film forming method and a film forming apparatus.

Priority is claimed on Japanese Patent Application No. 2006-272962, filed Oct. 4, 2006, the content of which is incorporated herein by reference.

### BACKGROUND ART

A plurality of thin film transistors are formed in a semiconductor device, such as an integrated circuit device. In recent years, in order to improve the operation speed of a semiconductor device, a technique has been developed which forms a source and a drain of a thin film transistor with a composite film of silicon and germanium (hereinafter, referred to as a ‘SiGe film’). In this case, a SiGe film is grown on the surface of a silicon substrate having impurities diffused therein.

If the surface of the silicon substrate is clean and is not covered with, for example, an oxide film, the SiGe film is aligned along a silicon crystal surface, which is a base. Therefore, it is possible to obtain a single crystal SiGe film. However, when an active silicon substrate is exposed to air, a natural oxide film is immediately formed on the silicon substrate.

When an oxide film is formed on the surface of the silicon substrate, the crystal of a precipitate film is not oriented in one direction, and a polycrystalline film is generated. When the temperature of the silicon substrate is low, the precipitate film is not crystallized, but becomes amorphous. Therefore, in order to grow a single crystal SiGe film, it is necessary to remove the natural oxide film on the silicon substrate.

In recent years, the following two methods have been used to remove the natural oxide film.

In a first method, first, a silicon substrate is inserted into a vacuum processing chamber, and the substrate is heated to about 1000° C. Then, a hydrogen gas or a mixed gas including the hydrogen gas is introduced into the processing chamber, and a natural oxide film on the surface of the silicon substrate is removed by the action of hydrogen to reduce a silicon oxide film (for example, see JP-A-2006-156875).

In a second method, a silicon substrate is inserted into a vacuum processing chamber and the substrate is heated to about 800° C. Then, gas including fluorine as a component or a mixed gas thereof is introduced into the processing chamber, and energy, such as high-frequency power, is supplied from the outside to excite the gas, thereby generating a fluorine radical. The fluorine radical reacts with a silicon oxide film to generate volatile silicon fluoride, thereby removing the natural oxide film.

### DISCLOSURE OF INVENTION

However, when a SiGe film used for the source and the drain of a thin film transistor is formed, it is necessary to remove a natural oxide film formed on the surface of a silicon substrate having impurities diffused therein. In this case, when the silicon substrate is heated to 800° C. or more, the diffusion profile of impurities is broken. Therefore, the first and second methods that heat the substrate to 800° C. or more are not preferable.

Further, in a method of removing a natural oxide film on the surface of a silicon substrate having no impurities diffused therein, when the substrate is heated to 800° C. or more, energy consumption increases. In addition, in order to increase the concentration of Ge to obtain a SiGe film having a fiat surface, it is necessary to lower the growth temperature of the SiGe film. In this case, it is necessary to heat the silicon substrate to 800° C. or more and then reduce the temperature of the silicon substrate to be within a low-temperature range. Therefore, it takes a long time to adjust the temperature of the silicon substrate.

The present invention has been made in order to solve the above-mentioned problems, and an object of the present invention is to provide a film forming method and a film forming apparatus capable of removing a natural oxide film of a silicon substrate at a low temperature and growing a single crystal SiGe film.

In order to achieve the object, according to an aspect of the present invention, a film forming method includes: a first step of converting a natural oxide film on a silicon substrate into a volatile material; a second step of evaporating the volatile material; and a third step of growing a composite film of silicon and germanium on the silicon substrate from which the natural oxide film is removed.

According to the first and second steps, it is possible to remove the natural oxide film on the silicon substrate at a low temperature. In this way, it is possible to make the maximum temperature of a SiGe film forming process equal to the growth temperature of the SiGe film. Therefore, it is possible to reduce the influence of heat on the silicon substrate.

In the first step, the natural oxide film may react with an ammonium fluoride gas to be converted into volatile ammonium fluorosilicate.

The first step may be performed while maintaining the temperature of the silicon substrate at 100° C. or less.

According to the above-mentioned structure, it is possible to convert a natural oxide film into a volatile material at a room temperature of 100° C. or less. Therefore, it is possible to remove the natural oxide film at a low temperature.

The second step may heat the silicon substrate to 100° C. or more. According to this structure, it is possible to accelerate the evaporation of a volatile material.

According to another aspect of the present invention, a film forming apparatus includes: a first processing chamber including a reactant gas supply unit that supplies a reactant gas for converting a natural oxide film on a silicon substrate into a volatile material and a heating unit that heats the silicon substrate; a second processing chamber including a raw gas supply unit that supplies a raw gas for growing a composite film of silicon and germanium on the silicon substrate; and a substrate transport chamber that transports the silicon substrate from the first processing chamber to the second processing chamber in a controlled atmosphere.

According to this structure, it is possible to remove the natural oxide film on the silicon substrate at a low temperature. In addition, the silicon substrate from which the natural oxide film is removed in the first processing chamber can be transported to the second processing chamber without being exposed to air. Therefore, it is possible to prevent a natural oxide film from being formed again. In this way, it is possible to grow a SiGe film on the silicon substrate from which the natural oxide film is removed, and obtain a single crystal SiGe film.

According to still another aspect of the present invention, a film forming apparatus includes: a first processing chamber including a reactant gas supply unit that supplies a reactant gas for converting a natural oxide film on a silicon substrate into a volatile material; a second processing chamber including a heating unit that heats the silicon substrate; a third processing chamber including a raw gas supply unit that supplies a raw gas for growing a composite film of silicon and germanium on the silicon substrate; and a substrate transport chamber that transports the silicon substrate among the processing chambers in a controlled atmosphere.

According to this structure, the silicon substrate from which the natural oxide film is removed in the first and second processing chambers can be transported to the third processing chamber without being exposed to air. Therefore, it is possible to prevent a natural oxide film from being formed again. As a result, it is possible to obtain a single crystal SiGe film.

According to yet another aspect of the present invention, a film forming apparatus includes: a processing chamber including a reactant gas supply unit that supplies a reactant gas for converting a natural oxide film on a silicon substrate into a volatile material, a heating unit that heats the silicon substrate, and a raw gas supply unit that supplies a raw gas for growing a composite film of silicon and germanium on the silicon substrate.

According to this structure, it is not necessary to transport the silicon substrate from which the natural oxide film is removed. Therefore, it is possible to prevent a natural oxide film from being formed again. As a result, it is possible to obtain a single crystal SiGe film.

The reactant gas supply unit may include a nitrogen trifluoride gas supply unit and a hydrogen radical supply unit.

According to this structure, in the first processing chamber, a nitrogen trifluoride gas and a hydrogen radical react with each other to generate an ammonium fluoride gas. In addition, the natural oxide film can be converted into volatile ammonium fluorosilicate by reaction with the ammonium fluoride gas. In this case, it is possible to convert a natural oxide film into a volatile material at a room temperature of 100° C. or less. Therefore, it is possible to remove a natural oxide film at a low temperature.

The heating unit may heat the silicon substrate to 100° C. or more.

According to this structure, it is possible to accelerate the evaporation of a volatile material.

According to the present invention, it is possible to remove a natural oxide film at a low temperature. In this way, it is possible to make the maximum temperature of a SiGe film forming process equal to the growth temperature of a SiGe film, and reduce the influence of heat on a silicon substrate. In addition, it is possible to grow a SiGe film on the silicon substrate from which the natural oxide film is removed while preventing a natural oxide film from being formed on the silicon substrate again. Therefore, it is possible to obtain a single crystal SiGe film.

### BRIEF DESCRIPTION OF THE DRAWINGS

FIG. 1 is a diagram schematically illustrating the structure of a natural oxide film removing apparatus.

FIG. 2 is a diagram schematically illustrating the structure of an etching chamber.

FIG. 3 is a flowchart illustrating a first process and a second process of a film forming method.

FIG. 4 is a diagram schematically illustrating the structure of a SiGe growing apparatus.

FIG. 5 is a flowchart illustrating a third process of the film forming method.

FIG. 6 is a diagram schematically illustrating the structure of a film forming apparatus according to a second embodiment.

FIG. 7 is a flowchart illustrating a film forming method.

FIG. 8 is a diagram schematically illustrating the structure of a film forming apparatus according to a first modification of the second embodiment.

FIG. 9 is a diagram schematically illustrating the structure of a film forming apparatus according to a second modification of the second embodiment.

### REFERENCE NUMERALS

W: Silicon substrate
3: Film forming apparatus
4: Film forming apparatus
16: Substrate transport chamber
20: Etching chamber (first processing chamber)
20a: First etching chamber (first processing chamber)
20b: Second etching chamber (second processing chamber)
24: Heater (heating unit)
30: Hydrogen radical supply unit (reactant gas supply unit)
35: Nitrogen trifluoride gas supply unit (reactant gas supply unit)
40: SiGe growing chamber (second processing chamber)
50: Raw gas supply unit
60: Processing chamber

### BEST MODE FOR CARRYING OUT THE INVENTION

Hereinafter, exemplary embodiments of the present invention will be described with reference to the accompanying drawings.

### First Embodiment

First, a first embodiment of the present invention will be described. A film forming method according to the first embodiment includes a first process of converting a natural oxide film of a silicon substrate into a volatile material, a second process of evaporating the volatile material, and a third process of growing a SiGe film on the silicon substrate from which the natural oxide film is removed.

### (Natural Oxide Film Removing Apparatus)

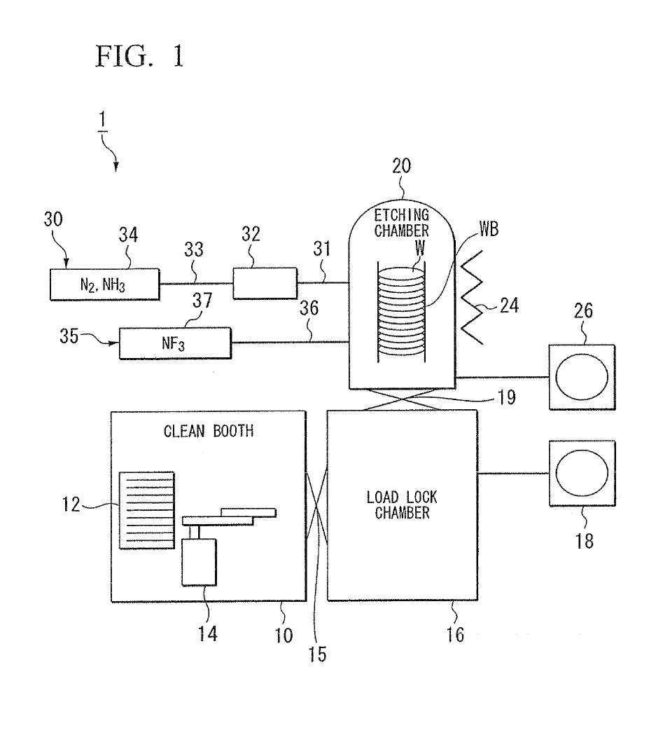

In the film forming method according to the first embodiment, the first process of converting a natural oxide film into a volatile material and the second process of evaporating the volatile material are performed by a natural oxide film removing apparatus shown in FIG. 1

A natural oxide film removing apparatus 1 shown in FIG. 1 includes a clean booth 10, a load lock chamber 16, and an etching chamber 20 as main components, and gate valves 15 and 19 are provided among the chambers. A substrate transport robot 14 is provided in the clean booth 10. The substrate transport robot 14 moves silicon substrates between a wafer cassette 12 arranged in the clean booth 10 and a wafer boat WB arranged in the load lock chamber 16. An exhaust pump 18, such as a turbo molecular pump, is connected to the load lock chamber 16. The load lock chamber 16 is evacuated by the exhaust pump 18.

The etching chamber 20 is formed such that the wafer boat WB having a plurality of silicon substrates W loaded therein at predetermined intervals in the thickness direction is carried therein. An exhaust pump 26, such as a turbo-molecular pump, is also connected to the etching chamber 20, and the etching chamber 20 is evacuated by the exhaust pump 26. A heater (heating unit) 24 that heats the silicon substrate W is provided inside or outside the etching chamber 20. The heater 24 heats the silicon substrate W to 100° C. or more.

A reactant gas supply unit that supplies a reactant gas for converting a natural oxide film on the silicon substrate W into a volatile material is provided in the etching chamber 20. In the first process, the natural oxide film reacts with an ammonium fluoride gas to be converted into volatile ammonium fluorosilicate. The ammonium fluoride gas is generated by introducing a nitrogen trifluoride gas and a hydrogen radical into the etching chamber 20. In this embodiment, as the reactant gas supply unit, a nitrogen trifluoride (NF₃) gas supply unit 35 and a hydrogen radical supply unit 30 are provided. The nitrogen trifluoride gas supply unit 35 includes a nitrogen trifluoride gas supply source 37 and a supply channel 36.

The hydrogen radical supply unit 30 excites an ammonia (NH₃) gas to generate a hydrogen radical. Therefore, the hydrogen radical supply unit 30 includes a supply source 34 that supplies an ammonia gas and a nitrogen (N₂) gas, which is a carrier gas of the ammonia gas. A microwave exciting mechanism 32 is provided in a gas supply channel 33 that extends from the gas supply source 34. The microwave exciting mechanism 32 radiates microwaves to generate plasma, and excites ammonia gas to generate a hydrogen radical. A hydrogen radical supply channel 31 extends from the microwave exciting mechanism 32 to the etching chamber 20.

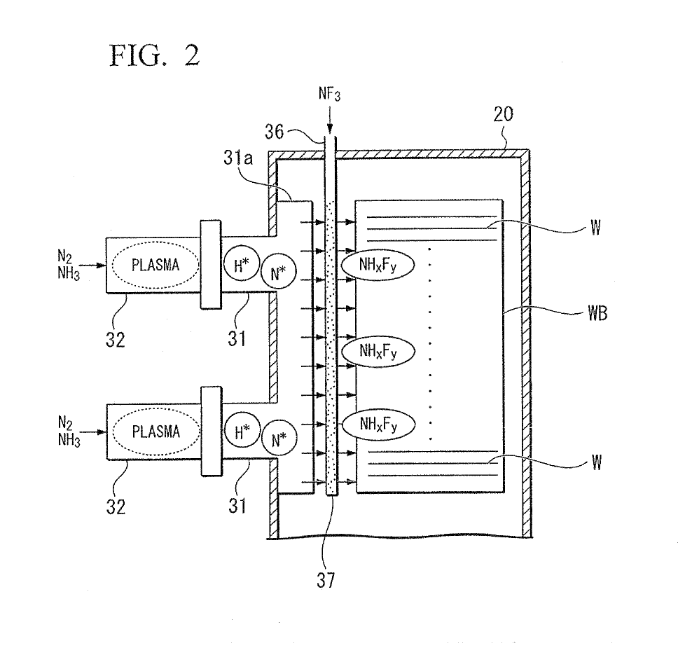

FIG. 2 is a diagram schematically illustrating the structure of the etching chamber. The wafer boat WB is carried in the etching chamber 20 such that the direction in which a plurality of silicon substrates W are arranged is aligned with the height direction of the etching chamber 20. A pair of hydrogen radical supply channels 31 are connected to the etching chamber 20 so as to be arranged at a predetermined interval in the height direction of the etching chamber 20. The pair of hydrogen radical supply channels 31 are connected to a hydrogen radical introduction head 31a that extends in the height direction of the etching chamber 20. The hydrogen radical is uniformly introduced into the etching chamber 20 in the height direction through a plurality of holes provided in the hydrogen radical introduction head 31a. It is preferable that a process for preventing the deactivation of a hydrogen radical (specifically, a process of coating a film made of aluminum hydrate, such as an alumite film) be performed on the inner wall of the etching chamber 20. In this way, it is possible to prevent the reaction between the inner wall of the etching chamber and the hydrogen radical and stably use the hydrogen radical for a substrate treatment. As a result, it is possible to improve the in-plane uniformity of a substrate.

The leading end of the nitrogen trifluoride gas supply channel 36 is inserted into the etching chamber 20 toward the bottom of the etching chamber through the ceiling. A shower nozzle 37 having a plurality of holes formed in the side surface thereof is formed at the leading end. A nitrogen trifluoride gas is uniformly introduced from the shower nozzle 37 into the etching chamber 20 in the height direction. The introduced nitrogen trifluoride gas reacts with the hydrogen radical to generate an ammonium fluoride (NHₓF_{y}) gas. In this way, the ammonium fluoride gas can uniformly react with a plurality of silicon substrates W arranged in the etching chamber 20 in the height direction.

### (First and Second Processes)

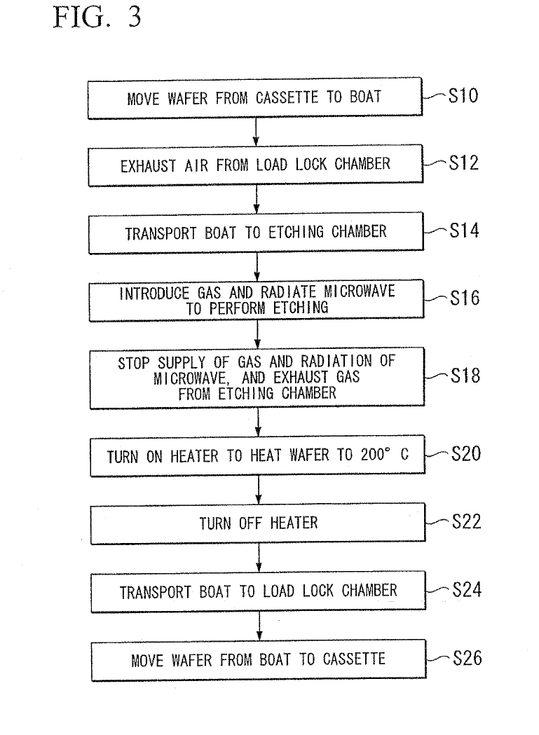

Next, the first process of converting a natural oxide film into a volatile material and the second process of evaporating the volatile material in the film forming method according to the first embodiment will be described with reference to FIGS. 1 and 3. FIG. 3 is a flowchart illustrating the first process and the second process.

First, the wafer cassette 12 having a plurality of silicon substrates W to be processed loaded therein is introduced into the clean booth 10, and the wafer boat WB without the silicon substrate W is arranged in the load lock chamber 16. Then, the gate valve 15 is opened and the substrate transport robot 14 is operated to move the silicon substrate W from the wafer cassette 12 to the wafer boat WB (S10). Then, the gate valve 15 is closed and the exhaust pump 18 is operated to exhaust air from the load lock chamber 16 (S12). Air is exhausted from the etching chamber 20 by the exhaust pump 26. Then, the gate valve 19 is opened and the wafer boat WB is transported from the load lock chamber 16 to the etching chamber 20 (S14).

Then, a reactant gas is introduced into the etching chamber 20 to convert a natural oxide film formed on the surface of the silicon substrate W into a volatile material (first process; S16). Specifically, the nitrogen trifluoride gas supply unit 35 introduces a nitrogen trifluoride gas, and the hydrogen radical supply unit 30 introduces a hydrogen radical. The gas supply source 34 of the hydrogen radical supply unit 30 supplies an ammonia gas, and the microwave exciting mechanism 32 radiates microwaves. In this way, the ammonia gas is excited, as represented by the following Chemical Formula 1, and a hydrogen radical (H*) is generated:

NH₃→NH₂+H*. [Chemical Formula 1]

In the etching chamber 20, the introduced nitrogen trifluoride gas reacts with the hydrogen radical to generate an ammonium fluoride (NHₓF_{y}) gas, as represented by the following Chemical Formula 2:

H*+NF₃→NHₓF_{y}(for example, NH₄F, NH₄FH, or NH₄FHF). [Chemical Formula 2]

The generated ammonium fluoride gas reacts with the natural oxide film formed on the surface of the silicon substrate W to generate volatile ammonium fluorosilicate ((NH₄)₂SiF₆), as represented by the following Chemical Formula 3:

SiO₂+NHₓF_{y}→(NH₄)₂SiF₆+H₂O. [Chemical Formula 3]

The generation reaction of ammonium fluorosilicate represented by Chemical Formula 3 is performed at a room temperature (about 25° C.). If the temperature of the silicon substrate is high, it is difficult to perform the generation reaction of ammonium fluorosilicate. Therefore, it is preferable that the first process be performed while maintaining the temperature of the silicon substrate W at 100° C. or less. In this way, it is possible to effectively generate ammonium fluorosilicate.

Then, the supply of the reactant gas and the radiation of microwaves stop, and gas is exhausted from the etching chamber 20 by the exhaust pump 26 (S18).

Then, the heater 24 is operated to heat the silicon substrate W, thereby evaporating the volatile material generated on the silicon substrate W (second process; S20). In the second process, the silicon substrate is heated to 100° C. or more, preferably 200 to 250° C. n this way, it is possible to effectively evaporate ammonium fluorosilicate, which is a volatile material.

Then, the operation of the heater stops (S22). Then, the gate valve 19 is opened, and the wafer boat WB is transported to the load lock chamber 16 (S24). Then, the gate valve 15 is opened, and the processed silicon substrates W are moved from the wafer boat WB to the wafer cassette 12 (S26).

### (SiGe Growing Apparatus)

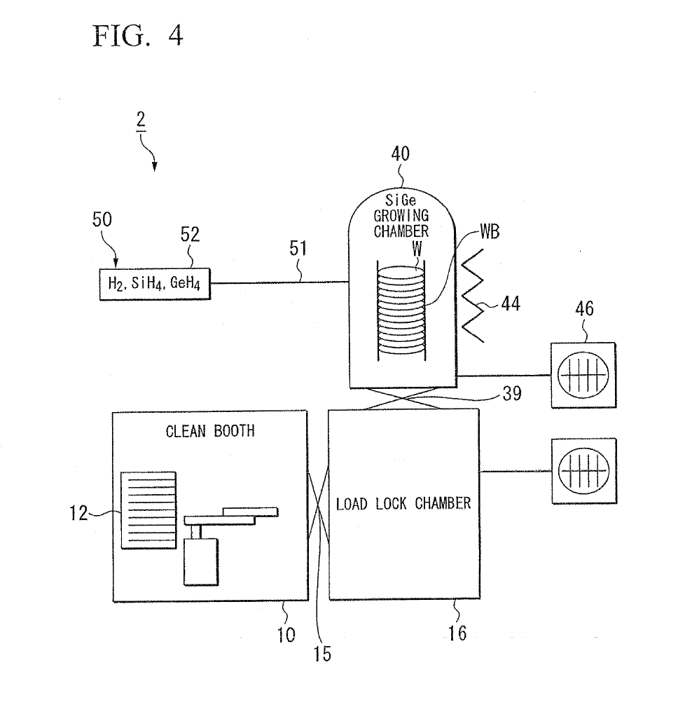

In the film forming method according to the first embodiment, the third process of growing a SiGe film on the silicon substrate is performed by a SiGe growing apparatus shown in FIG. 4.

A SiGe growing apparatus 2 shown in FIG. 4 includes a clean booth 10, a load lock chamber 16, and a SiGe growing chamber 40 as main components, and gate valves 15 and 39 are provided among the chambers. The clean booth 10 and the load lock chamber 16 have the same structures as those in the natural oxide film removing apparatus.

The SiGe growing chamber 40 is formed such that a wafer boat WB having a plurality of silicon substrates W loaded therein at predetermined intervals in the thickness direction is carried therein. An exhaust pump 46, such as a turbo-molecular pump, is connected to the SiGe growing chamber 40, and the SiGe growing chamber 40 is evacuated by the exhaust pump 46. A heater (heating unit) 44 that heats the silicon substrate W is provided inside or outside the SiGe growing chamber 40.

A raw gas supply unit 50 that supplies a raw gas for growing a composite film of silicon and germanium on a silicon substrate is provided in the SiGe growing chamber 40. The raw gas supply unit 50 includes a supply source 52 that supplies a hydrogen (H₂) gas, a silane (SiH₄) gas, and a germane (GeH₄) gas, which are raw gases, and a supply channel 51 of these gases.

### (Third Process)

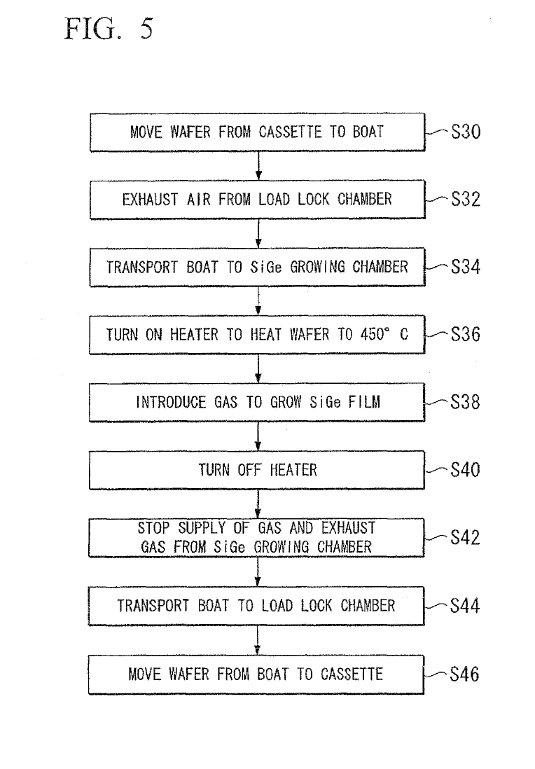

Next, the third process of growing a SiGe film on a silicon substrate in the film forming method according to the first embodiment will be described with reference to FIGS. 4 and 5. FIG. 5 is a flowchart illustrating the third process.

First, the silicon substrate W is moved from the wafer cassette 12 to the wafer boat WB (S30). Then, air is exhausted from the load lock chamber 16 (S32), and the wafer boat WB is transported from the load lock chamber 16 to the SiGe growing chamber 40 (S34).

Then, the heater 44 is operated to heat the silicon substrate W to 450° C. (to 700° C.) (S36). Then, a raw gas is introduced into the SiGe growing chamber 40 to grow a SiGe film (third process; S38). Specifically the raw gas supply unit 50 introduces a hydrogen gas, a silane gas, and a germane gas. These raw gases are thermally decomposed, as represented by the following Chemical Formulas 4 and 5:

SiH₄→Si+2H₂, and, [Chemical Formula 4]

GeH₄→Ge+2H₂. [Chemical Formula 5]

As such, since Si and Ge are simultaneously precipitated, a SiGe alloy film is formed on the silicon substrate W. In addition, since the natural oxide film is removed from the surface of the silicon substrate W, the SiGe film is aligned with a silicon crystal surface, which is a base, and a single crystal SiGe film is obtained.

Then, the operation of the heater stops (S40), the supply of the raw gas stops, and gas is exhausted from the SiGe growing chamber 40 (S42). Then, the wafer boat WB is transported to the load lock chamber 16 (S44), and the silicon substrate W is moved from the wafer boat WB to the wafer cassette 12 (S46). In this way, a silicon substrate W having a SiGe film formed thereon is obtained.

As described above, in the film forming method according to this embodiment, the first process of converting a natural oxide film formed on a silicon substrate into a volatile material and the second process of evaporating the volatile material are performed before the third process of growing a SiGe film on the silicon substrate. According to the first and second processes, it is possible to remove the natural oxide film formed on the silicon substrate at a low temperature. In this way, it is possible to makes the maximum temperature of a SiGe film forming process equal to the growth temperature of a SiGe film, and reduce the influence of heat on the silicon substrate. Therefore, it is possible to reduce the amount of energy consumed to heat the silicon substrate. In addition, since the temperature of the silicon substrate is increased from the first process to the third process in sequence, it is possible to shorten the time required to adjust the temperature of the silicon substrate. Therefore, it is possible to reduce the cost of forming a film.

### Second Embodiment

### Film Forming Apparatus

Next, a second embodiment of the present invention will be described.

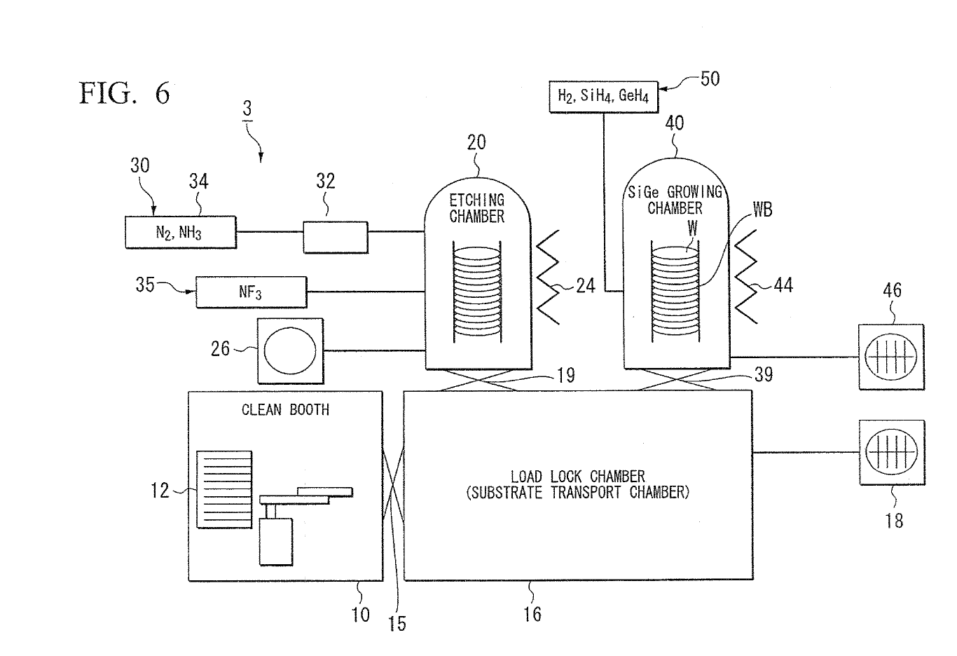

FIG. 6 is a diagram schematically the structure of a film forming apparatus according to the second embodiment. In the first embodiment, the natural oxide film removing apparatus including the etching chamber and the SiGe growing apparatus including the SiGe growing chamber are individually used. However, a film forming apparatus 3 according to the second embodiment includes an etching chamber (first processing chamber) 20, a SiGe growing chamber (second processing chamber) 40, and a substrate transport chamber 16 that transports a silicon substrate W from the etching chamber 20 to the SiGe growing chamber 40 in a controlled atmosphere. In the second embodiment, a detailed description of the same components as those in the first embodiment will be omitted.

The film forming apparatus 3 includes the etching chamber 20 and the SiGe growing chamber 40 in addition to the clean booth 10 and the load lock chamber 16. Similar to the first embodiment, the etching chamber 20 includes a reactant gas supply unit (a nitrogen trifluoride gas supply unit 35 and a hydrogen radical supply unit 30) that supplies a reactant gas for converting a natural oxide film on the silicon substrate W into a volatile material and a heater 24 that heats the silicon substrate W. Similar to the first embodiment, the SiGe growing chamber 40 includes a raw gas supply unit 50 that supplies a raw gas (a hydrogen gas, a silane gas, and a germane gas) for growing a SiGe film on the silicon substrate W. Similar to the first embodiment, an exhaust pump 26 is connected to the etching chamber 20, and an exhaust pump 46 is connected to the SiGe growing chamber 40.

The etching chamber 20 and the SiGe growing chamber 40 are connected to a common load lock chamber 16 through gate valves 19 and 39, respectively. The load lock chamber 16 includes gate valves 15, 19, and 39, and an exhaust pump 18, and controls an internal atmosphere. Therefore, the load lock chamber 16 serves as a substrate transport chamber that transports the silicon substrate W between the etching chamber 20 and the SiGe growing chamber 40 in a controlled atmosphere.

### (Film Forming Method)

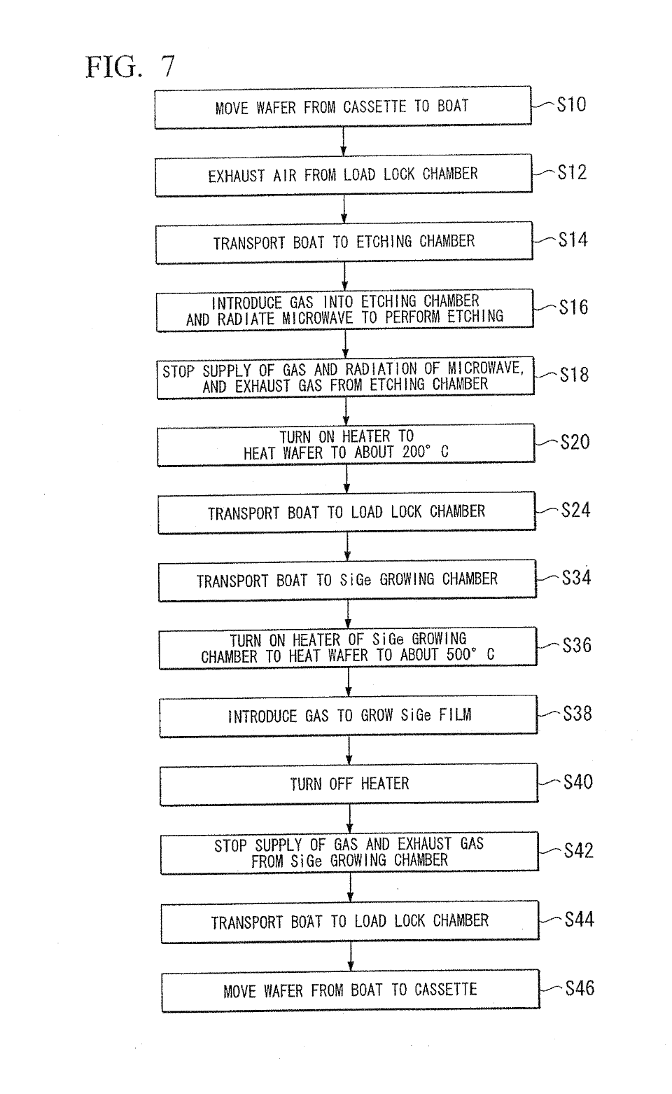

Next, a method of forming a film using the film forming apparatus 3 according to the second embodiment will be described with reference to FIGS. 6 and 7. FIG. 7 is a flowchart illustrating the film forming method according to the second embodiment.

First, the silicon substrate W is moved from a wafer cassette 12 arranged in the clean booth 10 to a wafer boat WB arranged in the load lock chamber (S10). Then, air is exhausted from the load lock chamber 16 (S12), and the wafer boat WB is transported from the load lock chamber 16 to the etching chamber 20 (S14).

Then, a reactant gas is introduced into the etching chamber to convert a natural oxide film formed on the surface of the silicon substrate W into a volatile material (first process; S16). Specifically, the nitrogen trifluoride gas supply unit 35 introduces a nitrogen trifluoride gas and the hydrogen radical supply unit 30 introduces a hydrogen radical. A gas supply source 34 of the hydrogen radical supply unit 30 supplies an ammonia gas, and a microwave exciting mechanism 32 radiates microwaves to excite the ammonia gas, thereby generating a hydrogen radical. In the etching chamber 20, the introduced nitrogen trifluoride gas reacts with the hydrogen radical to generate an ammonium fluoride gas. The ammonium fluoride gas acts on the natural oxide film formed on the surface of the silicon substrate W to generate volatile ammonium fluorosilicate.

Then, the supply of the reactant gas and the radiation of microwaves stop, and gas is exhausted from the etching chamber 20 by the exhaust pump 26 (S18).

Then, the heater 24 is operated to heat the silicon substrate W, thereby evaporating the volatile material generated on the silicon substrate W (second process; S20). In the second process, the silicon substrate is heated to 100° C. or more, preferably 200 to 250° C. to evaporate ammonium fluorosilicate, which is a volatile material. However, in the process of heating the silicon substrate W to 500° C. or more in the SiGe growing chamber 40 (S36), the volatile material generated on the silicon substrate may be evaporated, and is described below. Therefore, Step S20 may be omitted. In this case, it is not necessary to provide the heater 24 in the etching chamber 20.

Then, the gate valve 19 is opened, and the wafer boat WB is transported to the load lock chamber 16 (S24). Then, the gate valve 19 is closed and the gate valve 39 is opened. Then, the wafer boat WB is transported to the SiGe growing chamber 40 (S34). At that time, since air is exhausted from the load lock chamber 16 by the exhaust pump 18 and the load lock chamber is maintained in a controlled atmosphere (vacuum state), no natural oxide film is formed on the surface of the silicon substrate W again. Therefore, it is possible to carry a silicon substrate that is not covered with the natural oxide film into the SiGe growing chamber 40.

Then, the heater 44 of the SiGe growing chamber 40 is operated to heat the silicon substrate W to 500° C. (to 700° C.) (S36). When the process of heating the substrate W in the etching chamber 20 (S20) is omitted, the volatile material generated on the silicon substrate W is evaporated in Step S36 (second process). Then, a raw gas is introduced into the SiGe growing chamber 40 to grow a SiGe film (third process; S38). Specifically, the raw gas supply unit 50 introduces a hydrogen gas, a silane gas, and a germane gas. These raw gases are thermally decomposed, and Si and Ge are simultaneously precipitated. Therefore, a SiGe ally film is formed on the silicon substrate W.

Then, the operation of the heater stops (S40), the supply of the raw gas stops, and gas is exhausted from the SiGe growing chamber 40 (S42). Then, the wafer boat WB is transported to the load lock chamber 16 (S44), and the silicon substrate W is moved from the wafer boat WB to the wafer cassette 12 (S46). In this way, a silicon substrate W having a SiGe film formed thereon is obtained.

As described above, in the second embodiment, similar to the first embodiment, it is possible to remove a natural oxide film on a silicon substrate at a low temperature.

In addition, the film forming apparatus according to the second embodiment includes the etching chamber 20 and the SiGe growing chamber 40 that remove a natural oxide film, and the substrate transport chamber 16 that transports the silicon substrate W from the etching chamber 20 to the SiGe growing chamber 40 in a controlled atmosphere. According to this structure, it is possible to transport the silicon substrate W from which a natural oxide film is removed in the etching chamber 20 to the SiGe growing chamber 40 without exposing the silicon substrate to air, and prevent a natural oxide film from being formed again. As a result, it is possible to grow a SiGe film on the silicon substrate W from which the natural oxide film is removed, and obtain a single crystal SiGe film.

Since the film forming apparatus includes both the etching chamber 20 and the SiGe growing chamber 40, it is possible to shorten the transport time of a silicon substrate, and continuously perform the first to third processes. Therefore, it is possible to shorten the time required to form a film. In addition, the etching chamber 20 and the SiGe growing chamber 40 can share the clean booth 10 and the load lock chamber 16. Therefore, it is possible to reduce equipment costs.

The film forming apparatus 3 according to the second embodiment includes the reactant gas supply units 30 and 35 that supply a reactant gas for converting a natural oxide film on the silicon substrate W into a volatile material and the etching chamber 20 including the heater 24 that heats the silicon substrate W. It is possible to continuously perform the first process of converting a natural oxide film into a volatile material and the second process of evaporating the volatile material in the etching chamber 20. Instead of the film forming apparatus 3, a film forming apparatus including a first etching chamber having a reactant gas supply unit, a second etching chamber having a heater that heats a silicon substrate, and a common load lock chamber to which the first and second etching chambers are connected may be used. In the film forming apparatus, the first process is performed in the first etching chamber, and the second process is performed in the second etching chamber.

### (First Modification)

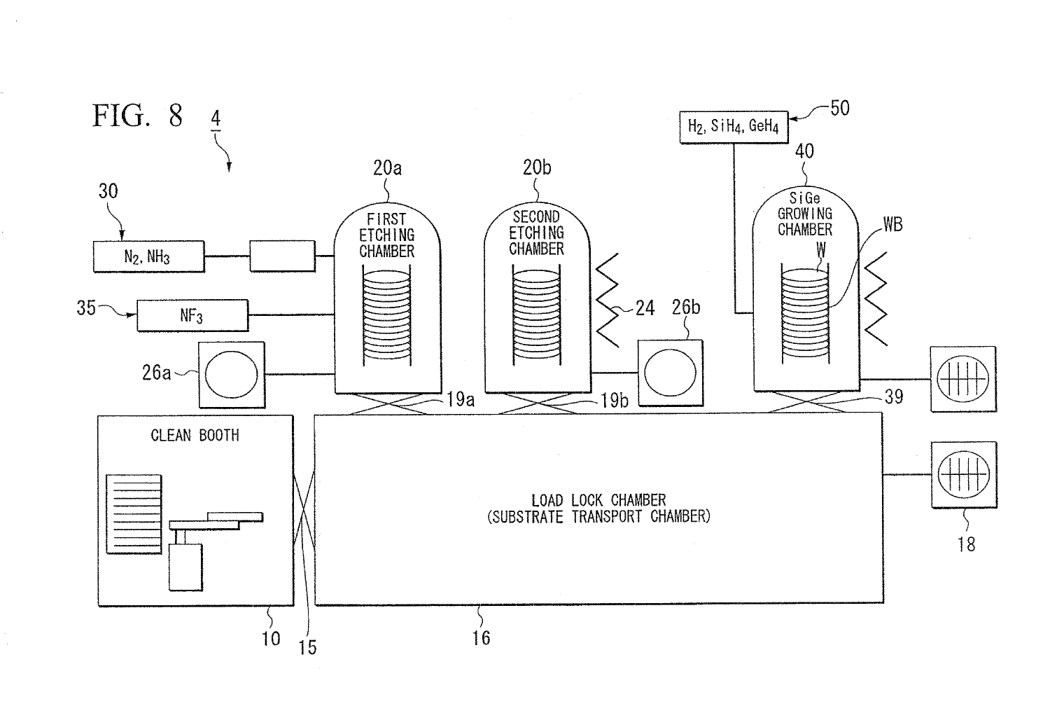

FIG. 8 is a diagram schematically illustrating the structure of a film forming apparatus according to a first modification of the second embodiment. In the second embodiment, the etching chamber including the reactant gas supply unit and the heater is used. However, the film forming apparatus according to the first modification differs from that according to the second embodiment in that it includes a first etching chamber 20a having a reactant gas supply unit and a second etching chamber 20b having a heater. In the first modification, a detailed description of the same components as those in the first embodiment or the second embodiment will be omitted.

A film forming apparatus 4 according to the first modification includes the first etching chamber (first processing chamber) 20a, the second etching chamber (second processing chamber) 20b, and the SiGe growing chamber (third processing chamber) 40 in addition to the clean booth 10 and the load lock chamber 16. The first etching chamber 20a includes a reactant gas supply unit (a nitrogen trifluoride gas supply unit 35 and a hydrogen radical supply unit 30) that supplies a reactant gas for converting a natural oxide film on the silicon substrate W into a volatile material. The second etching chamber 20b includes a heater 24 that heats the silicon substrate W. An exhaust pump 26a is connected to the first etching chamber 20a, and an exhaust pump 26b is connected to the second etching chamber 20b. The SiGe growing chamber 40 has the same structure as that in the first embodiment.

The first etching chamber 20a, the second etching chamber 20b, and the SiGe growing chamber 40 are connected to a common load lock chamber 16 through gate valves 19a, 19b, and 39, respectively. The load lock chamber 16 includes the gate valves 15, 19a, 19b, and 39, and an exhaust pump 18, and controls an internal atmosphere. Therefore, the load lock chamber 16 serves as a substrate transport chamber that transports the silicon substrate W among the first etching chamber 20a, the second etching chamber 20b, and the SiGe growing chamber 40 in a controlled atmosphere.

In the first modification, first, the first process of converting a natural oxide film on the silicon substrate W into a volatile material is performed in the first etching chamber 20a. Then, the silicon substrate W is transported from the first etching chamber 20a to the second etching chamber 20b through the substrate transport chamber 16 that is maintained in a controlled atmosphere (vacuum state). Then, the second process of evaporating the volatile material is performed in the second etching chamber 20b. Then, the silicon substrate W is transported from the second etching chamber 20b to the SiGe growing chamber 40 through the substrate transport chamber 16 that is maintained in a controlled atmosphere (vacuum state). Then, the third process of growing a SiGe film on the silicon substrate W is performed in the SiGe growing chamber 40.

According to the first modification, the silicon substrate W from which the natural oxide film is removed in the first etching chamber 20a and the second etching chamber 20b is transported to the SiGe growing chamber 40 without being exposed to air. Therefore, similar to the second embodiment, it is possible to prevent a natural oxide film from being formed again. In this way, it is possible to grow a SiGe film on the silicon substrate W from which the natural oxide film is removed, and obtain a single crystal SiGe film.

### (Second Modification)

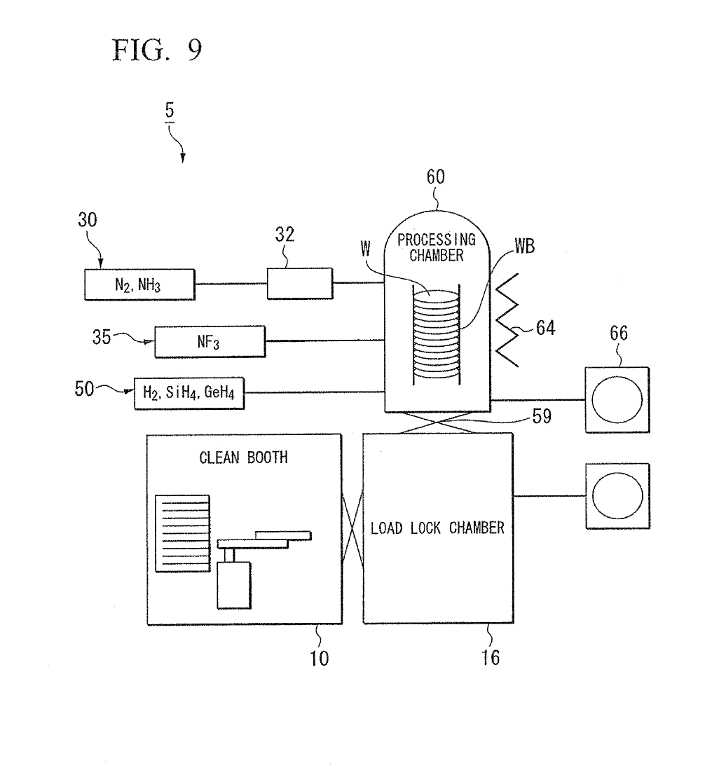

FIG. 9 is a diagram schematically illustrating the structure of a film forming apparatus according to a second modification of the second embodiment. In the second embodiment, the film forming apparatus includes both the etching chamber and the SiGe growing chamber. However, in the second modification, one processing chamber 60 serves as both the etching chamber and the SiGe growing chamber. In the second modification, a detailed description of the same components as those in the first embodiment or the second embodiment will be omitted.

A film forming apparatus 5 according to the second modification includes the processing chamber 60 in addition to the clean booth 10 and the load lock chamber 16. The processing chamber 60 is connected to the load lock chamber 16 through a gate valve 59. In addition, an exhaust pump 66 is connected to the processing chamber 60.

Similar to the first and second embodiments, the processing chamber 60 includes a reactant gas supply unit (a nitrogen trifluoride gas supply unit 35 and a hydrogen radical supply unit 30) that supplies a reactant gas for converting a natural oxide film on a silicon substrate W into a volatile material and a heater 64 that heats the silicon substrate W. In this way, the processing chamber 60 has the same function as that of the etching chamber according to the first and second embodiments. Similar to the first and second embodiments, the processing chamber 60 includes a raw gas supply unit 50 that supplies a raw gas (a hydrogen gas, a silane gas, and a germane gas) for growing a SiGe film on the silicon substrate W. In this way, the processing chamber 60 has the same function as that of the SiGe growing chamber according to the first and second embodiments.

In the second modification, first, a first process of converting a natural oxide film on the silicon substrate W into a volatile material and a second process of evaporating the volatile material are performed in the processing chamber 60. Then, a third process of growing a SiGe film on the silicon substrate W is performed with the silicon substrate W being held in the processing chamber 60.

According to the second modification, it is not necessary to transport the silicon substrate W from which the natural oxide film is removed. Therefore, similar to the second embodiment, it is possible to prevent a natural oxide film from being formed again. As a result, it is possible to grow a SiGe film on the silicon substrate W from which the natural oxide film is removed, and obtain a single crystal SiGe film.

In addition, in the second modification, it is not necessary to transport the silicon substrate W. Therefore, it is possible to continuously perform the first to third processes As a result, it is possible to shorten the time required to form a film. Furthermore, in the second modification, the chambers, the heaters, the exhaust pumps, and the gate valves provided in the etching chamber and the SiGe growing chamber in the second embodiment can be removed. As a result, it is possible to reduce equipment costs.

The technical scope of the present invention is not limited to the above-described embodiments, but various modifications and changes of the above-described embodiments can be made without departing from the scope and spirit of the present invention. That is, the detailed materials or structures exemplified in the above-described embodiments are just illustrative, and can be appropriately changed.

For example, in the above-described embodiments, the nitrogen trifluoride gas and the hydrogen radical are supplied as the reactant gas, but gases other than the above-mentioned gases may be supplied. In addition, in the above-described embodiments, the ammonia gas is excited to generate a hydrogen radical, but gases other than the ammonia gas may be excited. Further, in the above-described embodiments, microwaves are radiated to the ammonia gas to excite it, but the ammonia gas may be excited by methods other than the above-mentioned method. Furthermore, in the above-described embodiments, a silane gas and a germane gas are supplied as the raw gas, but gases other than the silane gas and the germane gas may be supplied.

### Example 1

Next, Example 1 corresponding to the first embodiment will be described.

A silicon substrate W was carried into the etching chamber 20 of the natural oxide film removing apparatus 1 shown in FIG. 1. An ammonia gas, a nitrogen gas, and a nitrogen trifluoride gas were introduced into the etching chamber 20 under the conditions of a mixture ratio of 1:2:2 and a total flow rate of 10 liter/minute, and the internal pressure of the etching chamber 20 was maintained at 300 Pa. In addition, microwaves were radiated to the ammonia gas and the nitrogen gas with a power of 2 kW for 10 minutes. Then, gas was exhausted from the etching chamber 20, and the silicon substrate W was heated to 200° C. and the temperature was maintained for 10 minutes.

Then, the silicon substrate W was carried into the SiGe growing chamber 40 of the SiGe growing apparatus 2 shown in FIG. 4. In the SiGe growing chamber 40, the silicon substrate W was heated to 450° C. Then, a silane gas was supplied at a flow rate of 100 cc/minute, a germane gas was supplied at a flow rate of 30 cc/minute, and a hydrogen gas was supplied at a flow rate of 300 cc/minute. Then, a mixed gas thereof was introduced into the SiGe growing chamber 40 for 30 minutes.

In this way, a (100)-oriented SiGe single crystal film having the same orientation as the silicon substrate was formed on the silicon substrate W. The thickness of the film was 50 nm, and the concentration of germanium was 45%.

### Example 2

Next, Example 2 corresponding to the second embodiment will be described.

A silicon substrate W was carried in the etching chamber 20 of the film removing apparatus 3 shown in FIG. 6. An ammonia gas, a nitrogen gas, and a nitrogen trifluoride gas were introduced into the etching chamber 20 under the conditions of a mixture ratio of 1:2:2 and a total flow rate of 10 liter/minute, and the internal pressure of the etching chamber 20 was maintained at 300 Pa. In addition, microwaves were radiated to the ammonia gas and the nitrogen gas with a power of 2 kW for 10 minutes.

Then, the silicon substrate W was carried from the etching chamber 20 to the SiGe growing chamber 40. In the SiGe growing chamber 40, the silicon substrate W was heated to 500° C. Then, a silane gas was supplied at a flow rate of 100 cc/minute, a germanium gas was supplied at a flow rate of 15 cc/minute, and a hydrogen gas was supplied at a flow rate of 150 cc/minute. Then, a mixed gas thereof was introduced into the SiGe growing chamber 40 for 30 minutes.

In this way, a (100)-oriented SiGe single crystal film having the same orientation as the silicon substrate was formed on the silicon substrate W. The thickness of the film was 90 nm, and the concentration of germanium was 25%.

### INDUSTRIAL APPLICABILITY

According to the present invention, it is possible to remove a natural oxide film at a low temperature. In this way, it is possible to make the maximum temperature of a SiGe film forming process equal to the growth temperature of a SiGe film, and reduce the influence of heat on a silicon substrate. In addition, it is possible to grow a SiGe film on the silicon substrate from which a natural oxide film is removed while preventing a natural oxide film from being formed on the silicon substrate again. Therefore, it is possible to obtain a single crystal SiGe film.

What is claimed is:

1. A film forming method comprising:
a first step of converting a natural oxide film on a silicon substrate into a volatile material;
a second step of evaporating the volatile material; and
a third step of growing a composite film of silicon and germanium on the silicon substrate from which the natural oxide film is removed.

2. The film forming method according to claim 1, wherein, in the first step, the natural oxide film reacts with an ammonium fluoride gas to be converted into volatile ammonium fluorosilicate.

3. The film forming method according to claim 1, wherein the first step is performed while maintaining the temperature of the silicon substrate at 100° C. or less.

4. The film forming method according to claim 1, where the second step heats the silicon substrate to 100° C. or more.

5. A film forming apparatus comprising:
a first processing chamber including a reactant gas supply unit that supplies a reactant gas for converting a natural oxide film on a silicon substrate into a volatile material and a heating unit that heats the silicon substrate;
a second processing chamber including a raw gas supply unit that supplies a raw gas for growing a composite film of silicon and germanium on the silicon substrate; and
a substrate transport chamber that transports the silicon substrate between the processing chambers in a controlled atmosphere.

6. A film forming apparatus comprising:
a first processing chamber including a reactant gas supply unit that supplies a reactant gas for converting a natural oxide film on a silicon substrate into a volatile material;
a second processing chamber including a heating unit that heats the silicon substrate;
a third processing chamber including a raw gas supply unit that supplies a raw gas for growing a composite film of silicon and germanium on the silicon substrate; and
a substrate transport chamber that transports the silicon substrate among the processing chambers in a controlled atmosphere.

7. A film forming apparatus comprising:
A processing chamber including a reactant gas supply unit that supplies a reactant gas for converting a natural oxide film on a silicon substrate into a volatile material, a heating unit that heats the silicon substrate, and a raw gas supply unit that supplies a raw gas for growing a composite film of silicon and germanium on the silicon substrate.

8. The film forming apparatus according to claim 5, wherein the reactant gas supply unit includes a nitrogen trifluoride gas supply unit and a hydrogen radical supply unit.

9. The film forming apparatus according to claim 6, wherein the reactant gas supply unit includes a nitrogen trifluoride gas supply unit and a hydrogen radical supply unit.

10. The film forming apparatus according to claim 7, wherein the reactant gas supply unit includes a nitrogen trifluoride gas supply unit and a hydrogen radical supply unit.

11. The film forming apparatus according to claim 5, wherein the heating unit heats the silicon substrate to 100° C. or more.

12. The film forming apparatus according to claim 6, wherein the heating unit heats the silicon substrate to 100° C. or more.

13. The film forming apparatus according to claim 7, wherein the heating unit heats the silicon substrate to 100° C. or more.
